(19) United States
(12) Patent Application Publication
(10) Pub. No.: US 2009/0206463 A1
(43) Pub. Date: Aug. 20, 2009

(54) SEMICONDUCTOR DEVICE, METHOD OF MANUFACTURING THE SAME, AND ELECTRONIC EQUIPMENT USING THE SAME

(75) Inventor: Takayuki Yoshida, Shiga (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/343,936

(22) Filed: Dec. 24, 2008

(30) Foreign Application Priority Data
Feb. 18, 2008 (JP) 2008-035416

(51) Int. Cl. H01L 23/28; H01L 21/56; H05K 1/11

(52) U.S. Cl. 257/686; 438/127; 174/255; 257/E23.116; 257/E21.502

(57) ABSTRACT

A semiconductor device includes a substrate 2, a semiconductor element 3, a molding resin portion 4, and a plurality of connection terminals 5 arranged on a surface of the substrate around the outer periphery of the molding resin portion 4. In a region B corresponding to a resin passage used to form the molding resin portion 4, a plurality of metal planes 18 and 19 as resin peel-off portions exhibiting a low adhesive strength to the molding resin are arranged in a direction along the resin passage at appropriate intervals. At least one connection terminal 5 is located between the metal planes 18 and 19.

### FIELD OF THE INVENTION

The present invention relates to a semiconductor device, a method of manufacturing the semiconductor device, and electronic equipment using the semiconductor device.

### BACKGROUND OF THE INVENTION

Efforts have been made to miniaturize portable electronic equipment such as cellular phones. There has been a demand for miniaturizing semiconductor devices arranged in the portable electronic equipment. Thus, some semiconductor devices include, for example, a first semiconductor element mounted on one surface of a first substrate, a molding resin portion covering the first semiconductor element, a second semiconductor element or a second substrate mounted above the molding resin portion via a conductive adhesive, and a first mounting electrode provided on the other surface of the first substrate for connection to a main substrate in the equipment.

A process of forming the molding resin portion uses a molding method of placing a mold on one surface of the first substrate with the first semiconductor element mounted thereon and pouring resin through a runner of the mold. In this case, to allow unwanted resin remaining on the first substrate to be efficiently removed, a metal peel-off surface to which the resin exhibits a low adhesion strength is continuously formed in a part of the first substrate corresponding to the runner, that is, from the outer peripheral portion of the substrate to a molding region (see, for example, Japanese Patent Laid-Open No. 6-120397).

However, if such a metal peel-off surface is formed, a connection terminal for the second semiconductor element and the like cannot be provided in the part corresponding to the runner. Since the recently miniaturized first substrate includes no space for the connection terminal, the size of the substrate needs to be increased by an amount corresponding to the metal peel-off surface. The semiconductor device thus has a size commensurate with the size of the substrate increased.

### DISCLOSURE OF THE INVENTION

In view of the above-described problems, an object of the present invention is to miniaturize a semiconductor device with the required number of connection terminals maintained therein.

To accomplish the object, a semiconductor device according to the present invention includes a first substrate, a first semiconductor element mounted on a first surface of the first substrate, a molding resin portion formed on the first surface and over the semiconductor element, and a plurality of first connection terminals arranged on the first surface and in a region around the outer periphery of the molding resin portion, wherein a plurality of resin peel-off portions exhibiting a low adhesive strength to the molding resin are arranged in a resin passage portion set in the first surface to allow the molding resin portion to be formed, and at least one of the resin peel-off portions is the first connection terminal.

The semiconductor device further includes a second substrate or a second semiconductor element located above the molding resin portion, and a conductive bonding portion connecting a second connection terminal formed on the second substrate or the second semiconductor element to the first connection terminal on the first substrate.

The semiconductor device includes a mounting electrode on a second surface of the first substrate to allow the semiconductor device to be mounted in electronic equipment.

The plurality of resin peel-off portions may be a first metal plane located in the region around the outer periphery of the mold resin portion, a second metal plane located in a peripheral part of the substrate, and at least one of the first connection terminals arranged between the first and second metal planes. The plurality of resin peel-off portions may all be the first connection terminals. The plurality of first connection terminals are preferably arranged in a line at predetermined intervals.

The region around the outer periphery of the molding resin portion is preferably covered with an insulating resin film except for surfaces of the first connection terminal and the resin peel-off portions, and is preferably subjected to plasma processing. In this case, in the resin passage portion, a surface of the insulating resin film which is subjected to plasma processing, particularly a surface thereof subjected to intensive plasma processing, functions as a resin peel-off portion.

The insulating resin film desirably contains a filler. The first metal plane can also be utilized as a position recognition pattern.

To manufacture the above-described semiconductor devices, at least the following steps are carried out: the step of mounting the first semiconductor element on the first surface of the first substrate so as to electrically connect the first semiconductor element to the first surface and carrying out plasma processing on a region around the outer periphery of a region in which the first semiconductor element is mounted, the step of setting the first substrate in a mold and pouring the molding resin through the resin passage portion to mold the first semiconductor element with the resin, and the step of removing the molding resin remaining in the resin passage portion.

When the region around the outer periphery of the molding region is covered with the insulating resin film except for the surfaces of the first connection terminals and the resin peel-off portions, the region is subjected to more intensive plasma processing than the other regions. The plasma processing may be carried out before or after mounting of the first semiconductor element.

The present invention is composed partly of a wiring substrate in which the semiconductor element mounting region and the molding region are set on the first substrate, that is, on the first surface, and the plurality of first connection terminals and the resin passage portion are arranged in the region around the outer periphery of the molding region, and in which the plurality of resin peel-off portions to which the molding resin exhibits a low adhesive strength are arranged in the resin passage portion, and at least one of the resin peel-off portions is the first connection terminal.

### BRIEF DESCRIPTION OF THE DRAWINGS

FIG. 1 is a sectional view of a semiconductor device according to an embodiment of the present invention;

FIGS. 2A, 2B, and 2C are sectional views showing a process of manufacturing the semiconductor device in FIG. 1;

FIG. 3 is a plan view of a substrate constituting the semiconductor device in FIG. 1;

FIG. 4A is an enlarged plan view showing a part of the substrate in FIG. 3, and FIG. 4B is a sectional view of the same part of the substrate; and

FIG. 5 is an enlarged plan view showing a part of another substrate according to the present invention.

### DESCRIPTION OF THE EMBODIMENTS

An embodiment of the present invention will be described below with reference to the drawings.

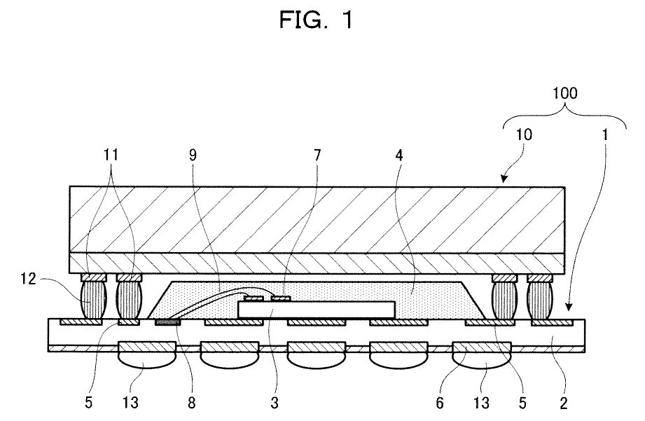

In FIG. 1, a semiconductor device 100 has a module structure made up of a first semiconductor device 1 and a second semiconductor device 10.

The semiconductor device 1 includes a substrate 2, a semiconductor element 3 mounted on one surface (hereinafter referred to as a substrate surface) of the substrate 2, a molding resin portion 4 formed on the substrate surface and over the semiconductor element 3, a plurality of connection terminals 5 and 8 formed on the substrate surface, and a plurality of connection terminals 6 and a plurality of mounting electrodes 13 formed on the back surface of the substrate.

Specifically, the substrate 2 is a wiring substrate, and a semiconductor element mounting portion is set in the middle of the substrate surface. The plurality of connection terminals 8 and 5 are respectively formed in a region corresponding to the inside of the molding resin portion 4 and a region around the outer periphery of the region corresponding to the inside of the molding resin portion 4. The plurality of connection terminals 6 are formed on the back surface of the substrate so as to connect electrically to the connection terminals 8 and 5. The mounting electrodes 13 are formed on the respective connection terminals 6.

The semiconductor element 3 is secured on the semiconductor element mounting portion of the substrate 2 with an insulating adhesive. Connection terminals 7 on the top surface of the element and the connection terminals 8 on the substrate 2 are electrically connected together by wires 9 (only some of the connection terminals and wires are shown).

The molding resin portion 4 is made up of a molding resin such as an epoxy resin and covers the semiconductor element 3, the connection terminals 8, and the wires 9. The mold resin portion 4 is configured to protect the semiconductor element 3 and the like from external impact.

The semiconductor device 10 includes a plurality of connection terminals 11 corresponding to the connection terminals 5 on the substrate 2. The semiconductor device 10 is located above the molding resin portion 4 and electrically and mechanically connected to the substrate 2 via the connection terminals 5 of the substrate and the connection terminals 11 of the semiconductor device 10 as well as ball-like conductive adhesives 12.

The semiconductor device 100 including the semiconductor devices 1 and 10 stacked in two stages is mounted on a main substrate of electronic equipment (not shown in the drawings), for example, portable electronic equipment such as a cellular phone so that the mounting electrodes 13 on the back surface of the substrate 2 are connected to mounting electrodes on a surface of the main substrate with a conductive adhesive.

In other words, the semiconductor device 100 has a module structure in which the semiconductor element 3 and the semiconductor device 10 are mounted on the substrate 2 in two stages. The semiconductor device 10 is, for example, a large-scale memory, but instead another substrate or semiconductor element may be mounted in the semiconductor device 100.

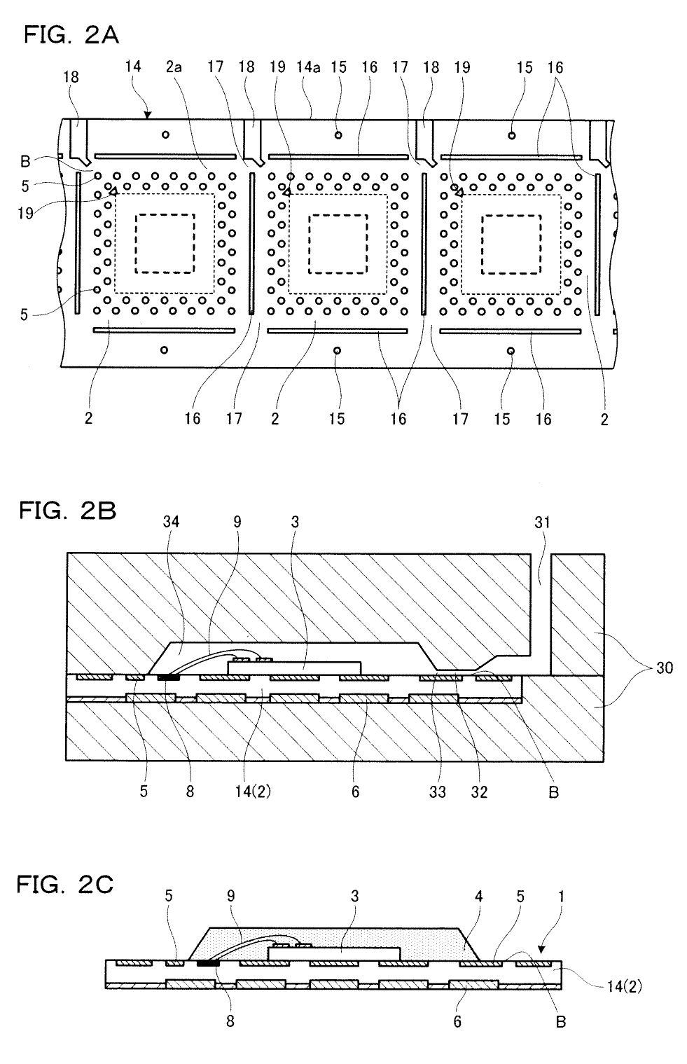

A method of manufacturing the semiconductor device 100 will be described in brief with reference to FIG. 2.

FIG. 2A shows a hoop-like substrate 14. The substrate 14 is obtained by connecting regions each corresponding to the above-described substrate 2. Kerfs 16 are formed all around the outer periphery of each substrate 2 region so that the substrate 14 is subsequently divided into the substrates 2.

In each substrate 2 region, the connection terminals 5 on the surface thereof are arranged, at predetermined intervals, in the region around the outer periphery of the molding resin portion 4 in a direction along the circumferential direction of the semiconductor element 3 and the molding resin portion 4. The connection terminals 5 are further concentrically arranged in two rows.

For each substrate 2 region, metal planes 18 and 19 are discontinuously formed in a region B located opposite a resin passage in a mold used to form the molding resin portion 4. The metal plane 18 is located so as to extend from a longitudinal side 14a of the substrate 14, through a kerf non-formation portion 17, and slightly into a corner portion in the substrate 2 region. The metal plane 19 is located on an extension of the metal plane 18. The connection terminals 5 are also arranged between the metal planes 18 and 19. The entire surface of the substrate 2 except for surfaces of the connection terminals 5 and metal planes 18 and 19 is covered with a resist 2a that is an insulating protect film. The metal planes 18 and 19 and the like will be described below in detail.

Reference numeral 15 denotes pilot holes formed in the substrate 14 along the longitudinal direction thereof at predetermined intervals. The pilot holes 15 allow a conveying operation, a processing operation, and a mounting operation to be continuously, easily performed.

As shown in FIGS. 2B and 2C, the semiconductor element 3 is mounted in each substrate 2 region in the substrate 14. The substrate 14 is set in a mold 30. A supply portion 31 communicating with a mold container (not shown in the drawings) is positioned around the outer periphery of the substrate 14. A runner 32 and a gate 33 are arranged opposite the region B. The semiconductor element 3 is accommodated in a mold space formed by a recess portion 34. In this condition, a molding resin is fed from the mold container through the runner 32 and the gate 33 into the mold space formed by the recess portion 34.

The molding resin is cured, and the substrate 14 with the molding resin portion 4 formed thereon is then removed from the mold 30. The substrate 14 is cut along the kerfs 16 (see FIG. 2A) with a cutter and thus divided into molded articles each corresponding to the substrate 2, that is, the semiconductor device 1.

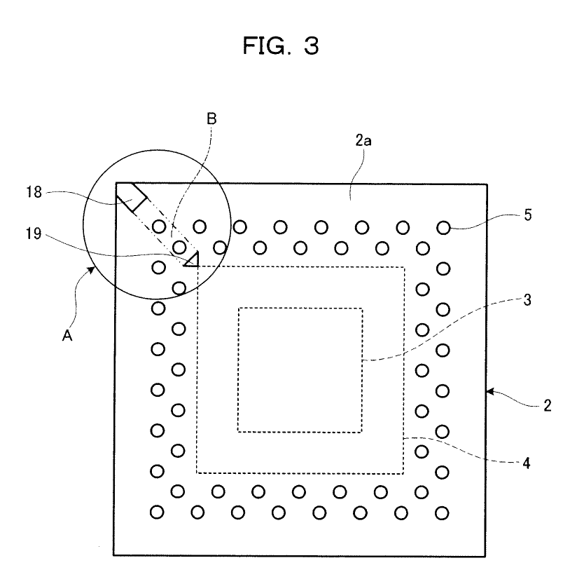

In this case, after the substrate 14 is removed from the mold 30 (before the substrate 14 is cut with the cutter), the unwanted molding resin remaining on the substrate 14 is removed. A measure described below is used to efficiently remove the molding resin. The measure will be described with reference to FIG. 3. For the sake of simplicity, FIG. 3 shows only the substrate 2 region after the cutting.

(1) As described above, the metal plane 19, the metal plane 18, and the connection terminal 5 are formed in the region B. The metal plane 18 is placed in a peripheral portion of the substrate in association with the runner of the mold. The metal plane 19 is placed in the region around the outer periphery of the region corresponding to the molding resin portion 4 in association with the gate of the mold. Between the linearly arranged metal planes 19 and 18, the two connection terminals 5 are similarly linearly arranged. At least the surfaces (top surfaces) of the metal plane 18, the two connection terminals 5, and the metal plane 19 are made of metal such as gold or silver so as to avoid tight contact with the molding resin.

(2) Plasma processing is carried out on the resist 2a, provided all over the surface of the substrate 2 except for the metal plane 18, the connection terminals 5, and the metal plane 19. The plasma processing may be carried out before or after the semiconductor element 3 is mounted on the substrate 2. Processing intensity is preferably varied between the inside of the region corresponding to the molding resin portion 4 and the region around the outer periphery of the region corresponding to the molding resin portion.

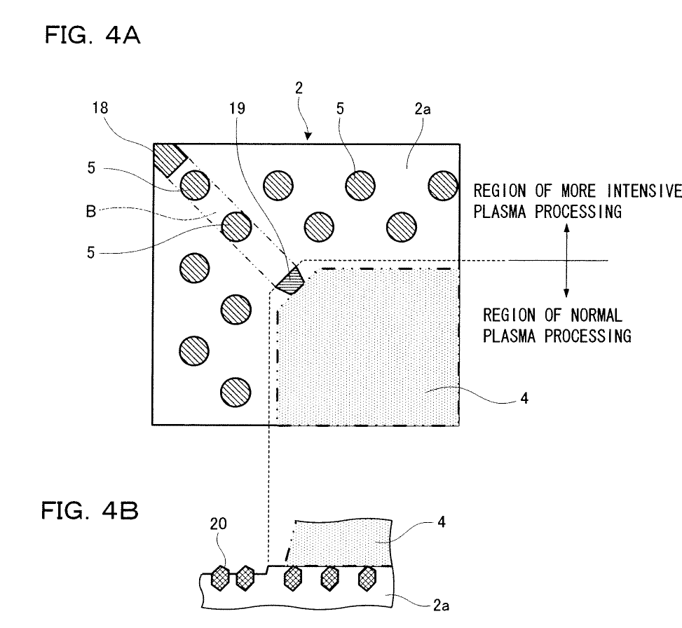

Specifically, as shown in the enlarged views in FIGS. 4A and 4B, plasma processing with a normal intensity is carried out on the inside of the region corresponding to the molding resin portion 4 in order to clean surfaces of the connection terminals 8 (see FIG. 1) and to enhance the adhesive strength between the resist 2a and the molding resin portion 4. On the other hand, plasma processing that is more intensive than that carried on the inside of the molding region is carried out on the region around the outer periphery of the molding region in order only to clean the surfaces of the metal plane 18, the two connection terminals 5, and the metal plane 19.

In this case, the molding resin is prevented from tightly contacting the metal plane 18, the two connection terminals 5, and the metal plane 19 and can thus be more easily removed. Furthermore, the electric connection of the connection terminals 5 and 8 is facilitated.

Moreover, the plasma processing with the high power facilitates removal of the molding resin remaining in the region B outside the substrate 2 region (see FIG. 2A). The reason for the facilitation of removal is not clear but is thought to be as follows.

The resist 2a is provided on the substrate 2 and contains a filler. When the intensive plasma processing abrades a surface of the resist 2a, a filler 20 is exposed as shown in FIG. 4B. Thus, the resist 2a may become loose to reduce the adhesive strength between the resist 2a and the molding resin, or the number of OH groups may decrease, thus reducing the adhesive strength between the resist 2a and the molding resin.

The decrease in OH groups will be described in detail. A material for the molding resin is designed such that a mold releasing agent (wax) is allowed to somewhat “unevenly” permeate a surface of the molding resin so as to allow the molding resin to be easily removed from the mold. The molding resin is bonded to OH groups in the resist 2a in areas in which the mold releasing agent is absent. However, compared to a resin component of the resist 2a, the filler 20, which contains Si (glass) or the like, contains a very small number of OH groups. The exposure of the filler 20 is thought to reduce the adhesive strength between the resist 2a and the molding resin.

In any event, the above-described structure and process enable the unwanted molding resin remaining on the substrate 2 to be easily removed.

Meanwhile, according to the present embodiment, the discontinuous metal planes 18 and 19 are provided in the region B, instead of a continuous metal plane as in the conventional art. Furthermore, the connection terminals 5 are provided in the region B. The present embodiment thus enables a reduction in the size of the substrate 2, on which the required number of the connection terminals 5 are provided, and thus a reduction in the sizes of the semiconductor devices 1 and 100, compared to the conventional art. Electronic equipment in which the semiconductor device 100 is mounted can also be miniaturized.

Furthermore, when located in one corner portion of the molding resin portion 4 as shown in the figures, the metal plane 19 can also be utilized as a mounting recognition mark. For example, when the semiconductor device 10 is mounted on the substrate 2, what is called first pins needs to be identified on both the semiconductor device 10 and the substrate 2 before the mounting operation is started. In this case, the metal plane 19 can be utilized as a mounting recognition mark for position recognition.

Without providing one or both of the metal planes 18 and 19 in the region B of the substrate 2, or by reducing the areas of the metal planes 18 and 19, new connection terminals 5 can be provided in the resulting empty area. In such a case, the new connection terminals 5 fulfill functions similar to those of the metal planes 18 and 19.

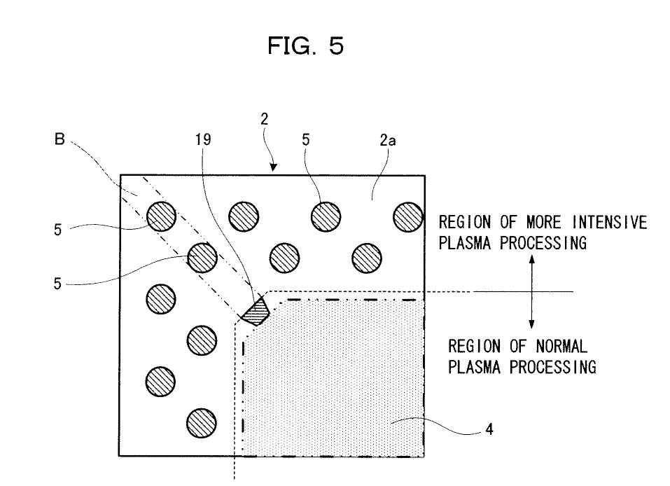

Alternatively, without providing one or both of the metal planes 18 and 19 in the region B of the substrate 2, or by reducing the areas of the metal planes 18 and 19, the resulting empty area can be covered with the resist 2a and subjected to more intensive plasma processing. In this case, the unwanted molding resin can also be easily removed. FIG. 5 shows that only the metal plane 19 is provided.

As described above, in the semiconductor device according to the present invention, the plurality of resin peel-off portions exhibiting a low adhesive strength to the molding resin are arranged, at the appropriate intervals, on the substrate surface corresponding to the resin passage in the mold. Furthermore, one of the resin peel-off portions is the connection terminal. That is, the connection terminal is provided in the part of the substrate in which in the conventional art, a metal peel-off surface is continuously formed, and is also utilized as a resin peel-off portion. Consequently, the present invention enables a reduction in the sizes of the substrate and the device compared to the conventional art, while providing the semiconductor device with the required number of connection terminals and allowing the molding resin to be efficiently removed. This contributes to reducing the size of and enhancing the functions of the electronic equipment in which the semiconductor device is mounted. The present invention is particularly useful for portable electronic equipment for which a size reduction is strongly demanded.

What is claimed is:

1. A semiconductor device comprising a first substrate, a first semiconductor element mounted on a first surface of the first substrate, a molding resin portion formed on the first surface and over the semiconductor element, and a plurality of first connection terminals arranged on the first surface and in a region around an outer periphery of the molding resin portion, wherein a plurality of resin peel-off portions exhibiting a low adhesive strength to the molding resin are arranged in a resin passage portion set in the first surface to allow the molding resin portion to be formed, and at least one of the resin peel-off portions is the first connection terminal.

2. The semiconductor device according to claim 1, wherein the plurality of resin peel-off portions are a first metal plane located in the region around the outer periphery of the mold resin portion, a second metal plane located in a peripheral part of the substrate, and at least one of the first connection terminals arranged between the first and second metal planes.

3. The semiconductor device according to claim 1, wherein the plurality of resin peel-off portions are all the first connection terminals.

4. The semiconductor device according to claim 1, wherein the region around the outer periphery of the molding resin is covered with an insulating resin film except for surfaces of the first connection terminal and the resin peel-off portions, and is subjected to plasma processing.

5. The semiconductor device according to claim 4, wherein in the resin passage portion, a surface of the insulating resin film subjected to the plasma processing also functions as a resin peel-off portion.

6. The semiconductor device according to claim 4, wherein the insulating resin film contains a filler.

7. The semiconductor device according to claim 2, wherein the first metal plane is also utilized as a position recognition pattern.

8. The semiconductor device according to claim 1, further comprising a second substrate or a second semiconductor element located above the molding resin, and a conductive bonding portion connecting a second connection terminal formed on the second substrate or the second semiconductor element to the first connection terminal on the first substrate.

9. The semiconductor device according to claim 1, comprising a mounting electrode on a second surface of the first substrate to allow the semiconductor device to be mounted in electronic equipment.

10. A method of manufacturing a semiconductor device, the method comprising the steps of:
using a first substrate wherein a semiconductor element mounting region and a molding region are set on a first surface, and a plurality of first connection terminals and a resin passage portion are arranged in a region around an outer periphery of the molding region, and wherein a plurality of resin peel-off portions to which the molding resin exhibits a low adhesive strength are arranged in the resin passage portion, and at least one of the resin peel-off portions is the first connection terminal, to mount a first semiconductor element on the first surface of the first substrate so as to electrically connect the first semiconductor element to the first surface and carrying out plasma processing on a region around an outer periphery of a region in which the first semiconductor element is mounted;
setting the first substrate in a mold and pouring a molding resin through the resin passage portion to mold the first semiconductor element with the resin; and
removing the molding resin remaining in the resin passage portion.

11. The method of manufacturing a semiconductor device according to claim 10, wherein the region around the outer periphery of the molding region is subjected to more intensive plasma processing.

12. The method of manufacturing a semiconductor device according to claim 10, wherein the plasma processing is carried out before or after mounting of the first semiconductor element.

13. A wiring substrate wherein a semiconductor element mounting region and a molding region are set on a first surface, and a plurality of first connection terminals and a resin passage portion are arranged in a region around an outer periphery of the molding region, and wherein a plurality of resin peel-off portions to which the molding resin exhibits a low adhesive strength are arranged in the resin passage portion, and at least one of the resin peel-off portions is the first connection terminal.
